(19) United States
(12) Patent Application Publication
(10) Pub. No.: US 2008/0315688 A1
(43) Pub. Date: Dec. 25, 2008

(54) PULSED POWER SUPPLY

(75) Inventors: Tatsuya Terazawa, Kasugai-City (JP); Takao Saito, Nagoya-City (JP)

Correspondence Address: BURR & BROWN, PO BOX 7068, SYRACUSE, NY, 13261-7068, US

(73) Assignee: NGK Insulators, Ltd., Nagoya-City (JP)

(21) Appl. No.: 12/136,113

(22) Filed: Jun. 10, 2008

Related U.S. Application Data
(60) Provisional application No. 60/947,505, filed on Jul. 2, 2007.

(30) Foreign Application Priority Data
Jun. 21, 2007 (JP) 2007-163974

(51) Int. Cl. H03K 3/64

(52) U.S. Cl. 307/106

(57) ABSTRACT

A pulsed power supply includes a DC power source, and a transformer and a switch which are connected in series with each other across the DC power source. The pulsed power supply operates to produce a plurality of high-voltage pulses in a repetition of cycles in each of which an induced energy is stored in the transformer when the switch is turned on and a high-voltage pulse is generated across a secondary winding of the transformer when the switch is turned off. The current flowing through the primary winding of the transformer is controlled to keep its peak value constant. The pulsed power supply further includes a current detector for detecting the current flowing through the primary winding of the transformer, and a third circuit for turning off the switch when the current detected by the current detector reaches the peak value.

### CROSS-REFERENCE TO RELATED APPLICATION

This application claims the benefit of U.S. Provisional Application Ser. No. 60/947,505 filed on Jul. 2, 2007, the entirety of which is incorporated herein by reference.

### BACKGROUND OF THE INVENTION

1. Field of the Invention

The present invention relates to a pulsed power supply of a simple circuit arrangement for releasing electromagnetic energy stored in a transformer from a DC power source having a low voltage thereby to supply a high-voltage pulse having a very short rise time and a very small pulse duration.

2. Description of the Related Art

For micromachining a workpiece according to electric discharging machining, it is necessary to employ a high-voltage pulse generating circuit for supplying high-voltage pulses having a very small pulse duration. Furthermore, technologies for deodorization, sterilization, and toxic gas decomposition based on a plasma developed by high-voltage pulse discharges have recently been put to use. To generate such a plasma, a high-voltage pulse generating circuit capable of supplying extremely narrow pulses of a high voltage is required.

There has heretofore been proposed a pulsed power supply employing a high-voltage pulse generating circuit as disclosed in Japanese patent No. 3811681, for example.

The proposed pulsed power supply does not employ a plurality of semiconductor switches to which a high voltage is applied, but is of a simple circuit arrangement that is capable of supplying a high-voltage pulse having a very short rise time and a very small pulse duration.

The proposed pulsed power supply produces a stable pulse output by employing an expensive DC stabilized power supply for generating a constant voltage and controlling the time for charging an exciting inductance to be constant.

The reason why the proposed pulsed power supply employs the expensive DC stabilized power supply is that if the DC voltage varies, then the charging energy also varies.

If a residual current remains with respect to the exciting inductance, then the induced energy in the next cycle becomes greater than the induced energy in the preceding cycle. A succession of such phenomena tends to cause the pulsed power supply to shut down due to overcurrent protection or tends to cause internal components of the pulsed power supply to be broken by an overcurrent, resulting in a reduction in the operational availability and reliability of the pulsed power supply.

The effect which a residual current has on the exciting inductance will be described below with reference to FIGS. 8 through 10 of the accompanying drawings.

As shown in FIG. 8, a pulsed power supply 200 according to the related art includes a transformer 204 and a switch 206 connected in series with each other across a DC power source 202, and a control circuit 208 for controlling the turning-on/off of the switch 206. The transformer 204 has a secondary winding connected to a diode 210 for supplying a current I2 in one direction to a load 212 that is connected to the secondary winding of the transformer 204.

When the switch 206 is turned on by the control circuit 208, the transformer 204 stores an induced energy. When the switch 206 is turned off by the control circuit 208, the transformer 204 generates a high voltage across the secondary winding thereof.

Normally, when the switch 206 is turned on at time t0 in FIG. 9, the same voltage as the voltage E of DC power source 202 is applied to the transformer 204. If the primary inductance of the transformer 204 is represented by L1, then a current I1 flowing through a primary winding 214 of the transformer 204 increases linearly with time at a gradient E/L1, storing an induced energy in the transformer 204.

During a turn-on period T1 in which the switch 206 is turned on, no voltage (0 V) is applied to the load 212 as the diode 210 is connected to the secondary winding of the transformer 204 to prevent a current from flowing therethrough.

When the switch 206 is subsequently turned off at time t1, a high pulsed voltage starts being applied to the load 212. Specifically, when the switch 206 is turned off, a pulsed negative electromotive force Vp1 is induced in the transformer 204, causing an abrupt current I2 to flow from the secondary winding in the forward direction of the diode 210. Now, a high pulsed negative voltage Vp2 depending on the induced electromotive force Vp1 is applied to the load 212.

After time t2 at the peak of the high pulsed negative voltage Vp2, the load 212 consumes the energy and the current I2 from the secondary winding is gradually reduced and reaches a reference level (0 A) at time t3 before the elapse of a predetermined turn-off period T2 of the switch 206.

If the current I2 from the secondary winding is not reduced sufficiently for some reason and does not reach the reference level (0 A) even after the elapse of the predetermined turn-off period T2, and a residual current Δi remains to flow from the secondary winding, as shown in FIG. 10, then the transformer 204 starts storing an induced energy in addition to a current depending on the residual current Δi at the start of a next turn-on period T1 in which the switch 206 is turned on. As a result, the transformer 204 stores an amount of induced energy which is greater than the amount of induced energy stored in the previous cycle.

If the DC power source 202 comprises a DC power source including an inexpensive rectifying circuit, then the voltage that is applied to the primary winding 214 of the transformer 204 tends to fluctuate during the period in which the induced energy is stored in the transformer 204. If the turn-on period T1 is constant, then the current I1 flowing through the primary winding 214 upon elapse of the turn-on period T1 also varies, resulting in a variation of the induced energy. Heretofore, it has thus been necessary to employ an expensive DC stabilized power source as the DC power source 202.

### SUMMARY OF THE INVENTION

It is an object of the present invention to provide a pulsed power supply which prevents an induced energy from being accumulatively stored due to a residual current, is capable of producing a stable pulsed output, is of improved operational availability and reliability, and incorporates an inexpensive DC power source.

Another object of the present invention is to provide a pulsed power supply which is capable of producing a stable pulsed plasma in various pressure environments ranging from vacuum to atmospheric pressure for various applications including plasma CVD, plasma PVD, plasma etching, plasma ion implantation, plasma surface modification, plasma electric discharge machining, etc., is capable of controlling the pulse duration of an output current depending on the workpiece to be processed in such applications, and is also capable of improving the quality of the workpiece to be processed in those applications.

A pulsed power supply according to the present invention includes a DC power source, a transformer and a switch which are connected in series with each other across the DC power source, wherein the pulsed power supply operates to produce a plurality of high-voltage pulses in a repetition of cycles in each of which an induced energy is stored in the transformer when the switch is turned on and a high-voltage pulse is generated across a secondary winding of the transformer when the switch is turned off, and a current control circuit for controlling a current flowing through a primary winding of the transformer to prevent an induced energy from being accumulatively stored over a plurality of cycles.

With the above arrangement, even if the pulsed power supply employs an inexpensive DC power source, it prevents the induced energy from fluctuating, also prevents the induced energy from being accumulatively stored due to a residual current, and is capable of producing a stable pulsed output. As the pulsed power supply is less susceptible to power fluctuations and the induced energy, the quality of a workpiece processed using the pulsed power supply is increased. The pulsed power supply is of increased operational availability because it can avoid an overcurrent failure.

The current control circuit may control the current flowing through the primary winding of the transformer to keep constant a peak value of the current.

The pulsed power supply may further comprise current detecting means for detecting the current flowing through the primary winding of the transformer, and control means for turning off the switch when the current detected by the current detecting means reaches the peak value. The current detecting means may comprise a contactless DC ammeter.

The pulsed power supply may further comprise a rectifying circuit for supplying a current in one direction through the secondary winding of the transformer, a second switch connected across the secondary winding of the transformer at a position closer to the transformer than the connected position of the rectifying circuit, and switching control means for turning on the second switch after elapse of a preset period from the time when the switch is turned off.

If a workpiece is processed by a plasma using the pulsed power supply in any of various applications including plasma CVD, plasma PVD, plasma etching, plasma ion implantation, plasma surface modification, plasma electric discharge machining, etc., then the pulsed power supply can produce a stable pulsed output, i.e., a stable pulsed plasma, and can control the pulse duration of its output current depending on the workpiece for increasing the quality of the processed workpiece.

Alternatively, the pulsed power supply may further comprise a rectifying circuit for supplying a current in one direction through the secondary winding of the transformer, a second switch connected across the primary winding of the transformer at a position closer to the transformer than the connected position of the switch, and switching control means for turning on the second switch after elapse of a preset period from the time when the switch is turned off.

Further alternatively, the pulsed power supply may further comprise a rectifying circuit for supplying a current in one direction through the secondary winding of the transformer, a winding disposed on a secondary side of the transformer separately from the secondary winding, the winding being of additive polarity with respect to the primary winding, and switching control means for turning on the second switch after elapse of a preset period from the time when the switch is turned off.

Preferably, a voltage applied across the second switch when the second switch is turned on is smaller than a forward voltage applied across the rectifying circuit. The second switch may comprise a series-connected circuit including a semiconductor switch and a second rectifying circuit which is forward-connected to the semiconductor switch.

As described above, even if the pulsed power supply according to the present invention employs an inexpensive DC power source, it prevents the induced energy from fluctuating, also prevents the induced energy from being accumulatively stored due to a residual current, and is capable of producing a stable pulsed output. The pulsed power supply is of increased operational availability and reliability. The quality of a workpiece processed using the pulsed power supply is increased.

Furthermore, if a workpiece is processed by a plasma using the pulsed power supply according to the present invention in any of various applications including plasma CVD, plasma PVD, plasma etching, plasma ion implantation, plasma surface modification, plasma electric discharge machining, etc., then the pulsed power supply can produce a stable pulsed output, i.e., a stable pulsed plasma, and can control the pulse duration of its output current depending on the workpiece for increasing the quality of the processed workpiece.

The above and other objects, features, and advantages of the present invention will become more apparent from the following description when taken in conjunction with the accompanying drawings in which preferred embodiments of the present invention are shown by way of illustrative example.

### BRIEF DESCRIPTION OF THE DRAWINGS

FIG. 1 is a circuit diagram of a first pulsed power supply;

FIG. 2 is a timing chart of a normal circuit operation of the first pulsed power supply;

FIG. 3 is a timing chart of a circuit operation of the first pulsed power supply at the time a residual current is generated;

FIG. 4 is a circuit diagram of a second pulsed power supply;

FIG. 5 is a timing chart of a circuit operation of the first pulsed power supply;

FIG. 6 is a circuit diagram of a third pulsed power supply;

FIG. 7 is a circuit diagram of a fourth pulsed power supply;

FIG. 8 is a circuit diagram of a pulsed power supply according to the related art;

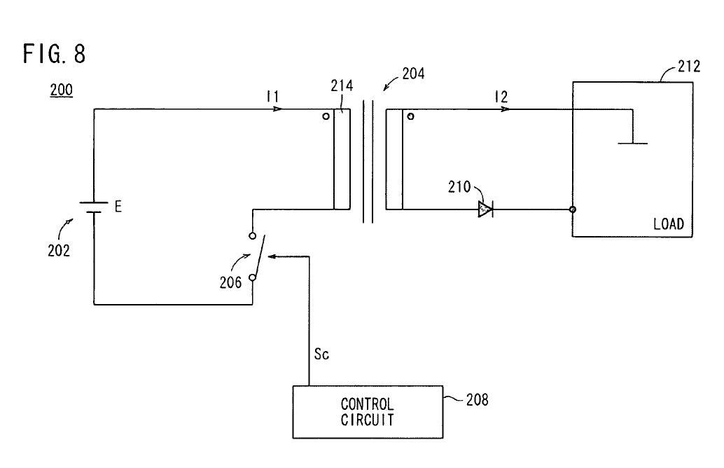

FIG. 9 is a timing chart of a normal circuit operation of the pulsed power supply according to the related art; and

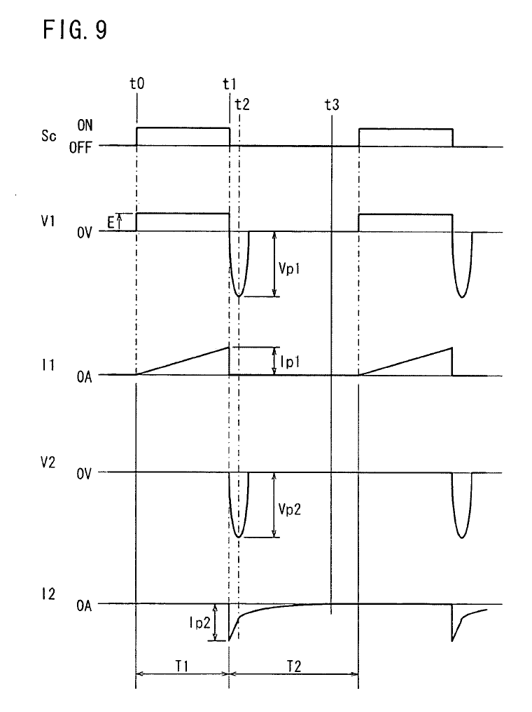

FIG. 10 is a timing chart of a circuit operation of the pulsed power supply according to the related art at the time a residual current is generated.

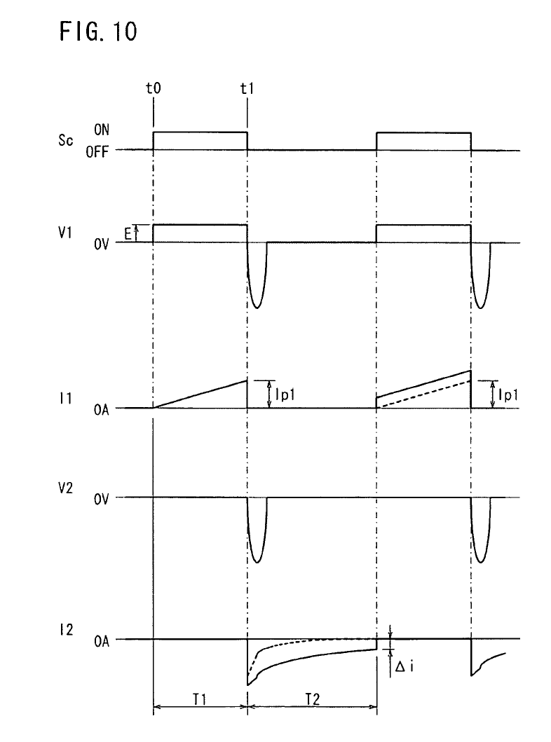

### DESCRIPTION OF THE PREFERRED EMBODIMENTS

Like or corresponding parts are denoted by like or corresponding reference characters throughout views.

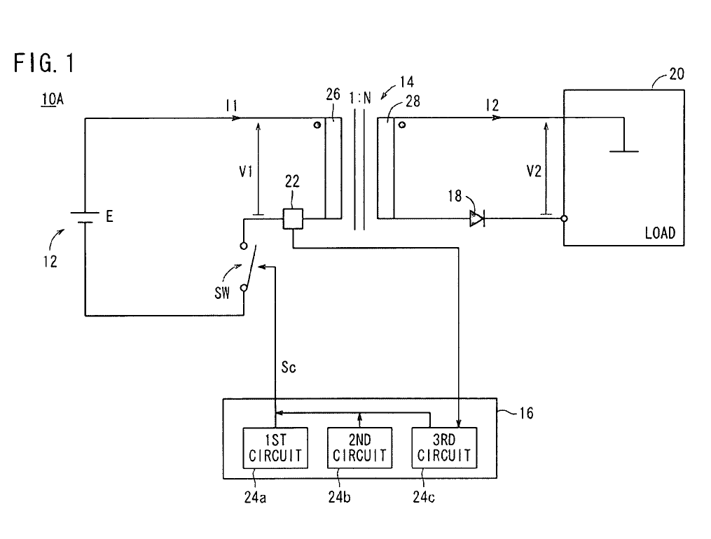

Pulsed power supplies according to preferred embodiments of the present invention will be described below with reference to FIGS. 1 through 7.

As shown in FIG. 1, a pulsed power supply 10A according to a first embodiment of the present invention (hereinafter referred to as “first pulsed power supply 10A”) comprises a transformer 14 and a switch SW connected in series with each other across a DC power source 12, and a control circuit 16 for controlling the turning-on/off of the switch SW. The transformer 14 has a secondary winding 28 connected to a rectifying circuit 18 for supplying a current I2 in one direction to a load 20 that is connected to the secondary winding 28 of the transformer 14.

The first pulsed power supply 10A operates in a repetition of cycles. In each of the cycles, an induced energy is stored in the transformer 14 when the switch SW is turned on and a high voltage is generated across the secondary winding 28 of the transformer 14 when the switch SW is turned off. Each of the cycles has a cycle period of 100 μsec (10 kHz), for example.

The first pulsed power supply 10A also includes a current detector 22 for detecting a current I1 flowing through a primary winding 26 of the transformer 14.

The control circuit 16 comprises a first circuit 24a for turning on the switch SW in response to a start signal, not shown, input thereto, a second circuit 24b for turning on the switch SW upon elapse of a predetermined turn-off period Toff from the time when the switch SW is turned off, and a third circuit 24c for turning off the switch SW at the time the current I1 detected by the current detector 22 reaches a predetermined peak value Ip1. Control signals from the first, second, and third circuits 24a, 24b, 24c for turning on and off the switch SW are output as a switching control signal Sc from the control circuit 16 and supplied to the switch SW.

The current detector 22 may be of any type insofar as it can detect the current I1 flowing through the primary winding 26 of the transformer 14. Preferably, the current detector 22 should be a contactless DC ammeter comprising a DCCT (direct-current current transformer) or the like.

The current detector 22 and the third circuit 24c jointly make up a current control circuit for keeping constant the peak value Ip1 of the current I1 flowing through the primary winding 26 of the transformer 14.

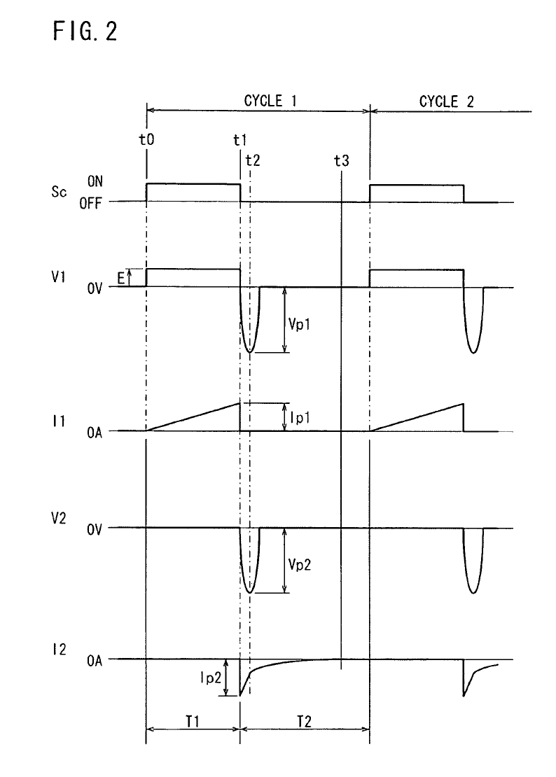

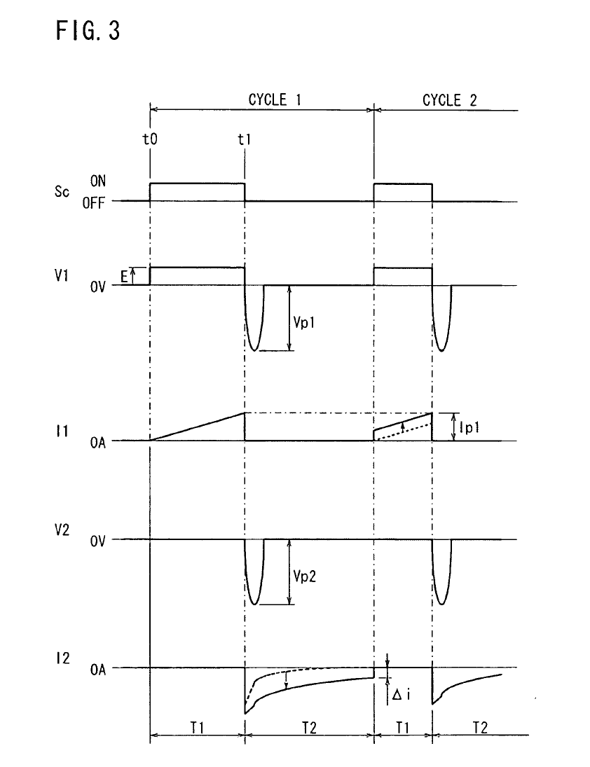

Circuit operation of the first pulsed power supply 10A will be described below with reference to FIGS. 2 and 3.

When the switch SW is turned on at start time t0 of cycle 1 in response to a start signal input thereto, substantially the same voltage as the voltage E of DC power source 12 is applied to the transformer 14. If the primary inductance of the transformer 14 is represented by L1, then the current I1 flowing through the primary winding 26 of the transformer 14 increases linearly with time at a gradient E/L1, storing an induced energy in the transformer 14.

During a turn-on period T1 in which the switch 206 is turned on, no voltage (0 V) is applied to the load 20 as the rectifying circuit 18 is connected to the secondary winding 28 of the transformer 14 to prevent a current from flowing therethrough.

Thereafter, the switch SW is turned off at time t1 when the current I1 flowing through the primary winding 26 reaches the predetermined peak value Ip1. When the switch SW is turned off, a high pulsed voltage starts being supplied to the load 20. If voltage E of DC power source 12 is 100 V, the turn-on time T1 is 20 μsec, and the primary inductance L1 of the transformer 14 is 20 μH, then the peak value Ip1 is given as follows:

$$\begin{matrix}Ip 1 = E \times T 1 \text{/} L 1 \\ = 100 V \times 20 µsec \text{/} 20 µH \\ = 100 A\end{matrix}$$

When the switch SW is turned off, the transformer 14 generates a pulsed negative electromotive force Vp1 induced therein which ranges from—several 100 V to—4 kV, for example, causing an abrupt current I2 to flow from the secondary winding 28 in the forward direction of the rectifying circuit 18. Now, a high pulsed negative voltage Vp2 which ranges from several to 20 kV depending on the induced electromotive force Vp1 is applied to the load 20.

If the ratio 1:N of the number of turns of the primary winding 26 to the number of turns of the secondary winding 28 is 1:5 and an attenuation a due to a switching loss is 2, then a peak value Ip2 of the current I2 flowing from the secondary winding 28 is given as follows:

$$\begin{matrix}Ip 2 = ( Ip 1 \text{/} N ) - α \\ = ( 100 A \text{/} 5 ) - 2 \\ = 18 A\end{matrix}$$

The ratio 1:N between the numbers of turns will be referred to as the ratio N.

After time t2 at the peak of the high pulsed negative voltage Vp2, the load 20 consumes the energy and the current I2 from the secondary winding 28 is gradually reduced and reaches a reference level (0 A) at time t3 before the elapse of a predetermined turn-off period T2 of the switch SW.

When the predetermined turn-off period T2 elapses, cycle 2 starts in which the pulsed power supply 10A operates in the same manner as with cycle 1.

If the current I2 from the secondary winding 28 is not reduced sufficiently for some reason and does not reach the reference level (0 A) even after the elapse of the predetermined turn-off period T2, and a residual current Δi remains to flow from the secondary winding 28, as shown in FIG. 3, then the transformer 14 starts storing an induced energy in addition to a current depending on the residual current Δi at the start of a next turn-on period T1 in which the switch SW is turned on.

With the first pulsed power supply 10A, the switch SW is turned off at the time when the current I1 flowing through the primary winding 26 reaches the predetermined peak value Ip1. Therefore, the amount of induced energy stored in the turn-on period T1 of the switch SW is prevented from being greater than the amount of induced energy stored in the previous cycle.

As described above, the first pulsed power supply 10A includes the current detector 22 for detecting the current I1 flowing through the primary winding 26 of the transformer 14, and the third circuit 24c for turning off the switch SW at the time the current I1 detected by the current detector 22 reaches the predetermined peak value Ip1. Accordingly, the induced energy is prevented from varying even if the DC power source 12 comprises an inexpensive DC power source. The pulsed power supply 10A also prevents the induced energy from being accumulatively stored due to the residual current, is capable of producing a stable pulsed output, and is of improved operational availability and reliability. The pulsed power supply 10A is further effective to increase the quality of a workpiece which is processed in various applications using the pulsed power supply 10A.

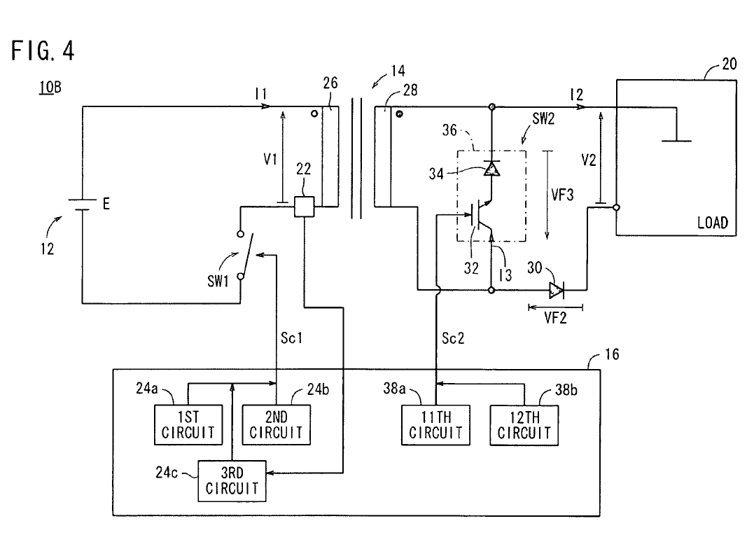

FIG. 4 shows a pulsed power supply 10B according to a second embodiment of the present invention (hereinafter referred to as “second pulsed power supply 10B”).

As shown in FIG. 4, the pulsed power supply 10B comprises a transformer 14 and a first switch SW1 connected in series with each other across a DC power source 12, a control circuit 16 for controlling the turning-on/off of the first switch SW, and a current detector 22 for detecting a current I1 flowing through a primary winding 26 of the transformer 14. The transformer 14 has a secondary winding 28 connected to a first rectifying circuit 30 for supplying a current I2 in one direction to a load 20 that is connected to the secondary winding 28 of the transformer 14.

The second pulsed power supply 10B also includes a second switch SW2 connected across the secondary winding 28 at a position closer to the transformer 14 than the connected position of the rectifying circuit 30. The second switch SW2 comprises a series-connected circuit 36 of an IGBT (Insulated-Gate Bipolar Transistor, hereinafter referred to as “bipolar transistor”) 32 and a second rectifying circuit 34 forward-connected to the bipolar transistor 32. Specifically, the bipolar transistor 32 has a collector connected to a negative terminal of the secondary winding 28 of the transformer 14, an emitter connected to the second rectifying circuit 34, and a gate connected to the control circuit 16. The second rectifying circuit 34 is connected between the emitter of the bipolar transistor 32 and a positive terminal of the secondary winding 28 of the transformer 14. If the second rectifying circuit 34 comprises one or more series-connected diodes, the cathode thereof is connected to the positive terminal of the secondary winding 28 and the anode is connected between the emitter of the bipolar transistor 32. The second switch SW2 may include a plurality of series-connected bipolar transistors 32 for making the second switch SW2 resistant to high voltages.

A voltage VF3 which is applied across the second switch SW2, particularly a voltage applied across the second switch SW2 when the second switch SW2 is turned on (a forward voltage applied across the series-connected circuit 36 when the bipolar transistor 32 is turned on, hereinafter referred to as “across voltage VF3 (turned-on voltage)”) is smaller than a voltage VF2 across the first rectifying circuit 30, particularly a forward voltage across the first rectifying circuit 30 (hereinafter referred to as “across voltage VF2 (forward voltage)”) (the across voltage (turned-on voltage) VF3<the across voltage VF2 (forward voltage)). When a current of 10 A flows in a forward direction through the first rectifying circuit 30 and the series-connected circuit 36, the across voltage VF2 (forward voltage) of the first rectifying circuit 30 is about 20 V and the across voltage VF3 (turned-on voltage) is about 5 V.

If the first rectifying circuit 30 comprises a plurality of series-connected diodes, then the across voltage (turned-on voltage) VF3 may be made smaller than the across voltage VF2 (forward voltage) by adjusting the number of series-connected diodes of the first rectifying circuit 30.

In FIG. 4, the first rectifying circuit 30 is shown as being connected between the negative terminal of the secondary winding 28 and the load 20. However, the first rectifying circuit 30 may be connected between the positive terminal of the secondary winding 28 and the load 20.

The control circuit 16 comprises first, second, and third circuits 24a, 24b, 24c which are identical to those of the first pulsed power supply 10A described above, for outputting a first switching control signal Sc1, an eleventh circuit 38a for turning on the second switch SW2 after elapse of a preset period T3 from the time when the first switch SW1 is turned off, and a twelfth circuit 38b for turning off the second switch SW2 at the time when the first switch SW1 is turned on. The period T3 may be preset by finding, in advance, a condition (the pulse duration of an output current) matching the workpiece to be processed using the second pulsed power supply 10B, and determining the delay of a delay circuit, for example, incorporated in the eleventh circuit 38a.

Control signals from the eleventh circuit 38a and the twelfth circuit 38b for turning on and off the second switch SW2 are output from the control circuit 16 as a second switching control signal Sc2 to the second switch SW2, i.e., the gate of the bipolar transistor 32.

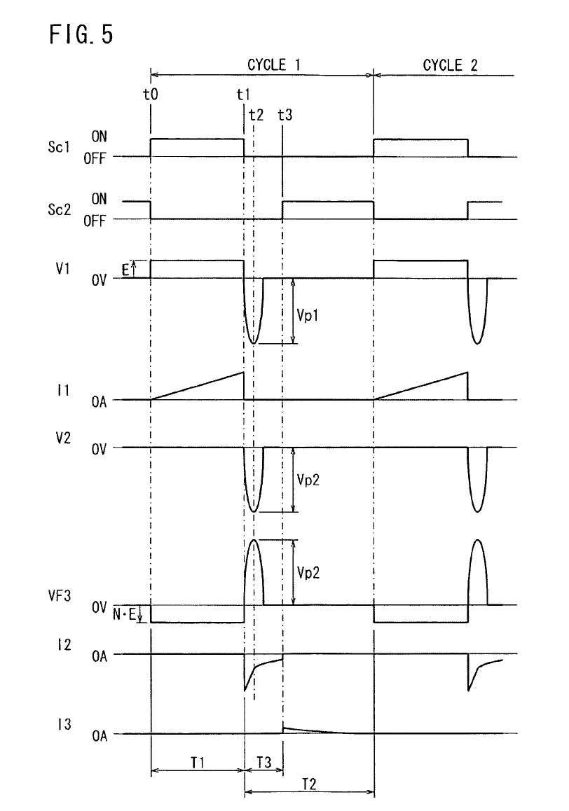

Circuit operation of the second pulsed power supply 10B will be described below with reference to FIG. 5.

When the first switch SW1 is turned on at start time t0 of cycle 1 in response to a start signal input thereto, substantially the same voltage as the voltage E of DC power source 12 is applied to the transformer 14. If the primary inductance of the transformer 14 is represented by L1, then the current I1 flowing through the primary winding 26 of the transformer 14 increases linearly with time at a gradient E/L1, storing an induced energy in the transformer 14. At this time, the across voltage VF3 of the series-connected circuit 36 of the second switch SW2 is equal to a voltage of 500 V, for example, that is produced by multiplying the voltage E by the ratio N.

At time t1 upon elapse of a certain period (the turn-on period T1) from start time t0 when the first switch SW1 is turned on, e.g., upon elapse of a period of 20 μsec, for example, until the current I1 flowing through the primary winding 26 reaches a predetermined peak value Ip1, the first switch SW1 is turned off, starting to supply a high pulsed voltage to the load 20.

When the first switch SW1 is turned off, a pulsed negative electromotive force Vp1 is induced in the transformer 14, causing an abrupt current I2 to flow from the secondary winding 28 in the forward direction of the first rectifying circuit 30. Now, a high pulsed negative voltage Vp2 depending on the induced electromotive force Vp1 is applied to the load 20. At this time, the across voltage of the series-connected circuit of the second switch SW2 is also equal to the high voltage Vp2.

After time t2 at the peak of the high pulsed negative voltage Vp2, the load 20 consumes the energy and the current I2 from the secondary winding 28 is gradually reduced. At time t3 when a certain time has elapsed from time t1 when the first switch SW1 was turned off, e.g., a period T3 of 1 μsec has elapsed while the output current I2 is flowing after the pulsed negative voltage Vp2 was output, the second switch SW2 is turned on.

When the second switch SW2 is turned on, the current I2 from the secondary winding 28 flows through the second switch SW2 which is lower in resistance than the first rectifying circuit 30. In other words, the current I2 from the secondary winding 28 does not flow into the load 20, but flows as a current I3 through a shorter path from the second switch SW2 to the secondary winding 28 of the transformer 14 to the second switch SW2. Therefore, the current I2 undergoes a smaller energy attenuation than if it flowed into the load 20. Though a residual current may tend to be generated with respect to the exciting inductance, since the current detector 22 and the third circuit 24c operate to keep constant the peak value Ip1 of the current I1 flowing through the primary winding 26 of the transformer 14, an induced energy is prevented from being accumulatively stored by the residual current.

In the second pulsed power supply 10B, the second switch SW2 is connected across the secondary winding 28 at a position closer to the transformer 14 than the connected position of the rectifying circuit 30, and is turned on after elapse of the preset period T3 from the time when the first switch SW1 is turned off. If a workpiece is processed by a plasma using the second pulsed power supply 10B in any of various applications including plasma CVD, plasma PVD, plasma etching, plasma ion implantation, plasma surface modification, plasma electric discharge machining, etc., then the second pulsed power supply 10B can control the pulse duration (=T3) of its output current depending on the workpiece for increasing the quality of the processed workpiece. As with the first pulsed power supply 10A, even if the induced energy fluctuates, the second pulsed power supply 10B prevents a residual current from being generated and can produce a stable pulsed output for improved operational availability and reliability. The second pulsed power supply 10B can also employ an inexpensive DC power source as the DC power source 12.

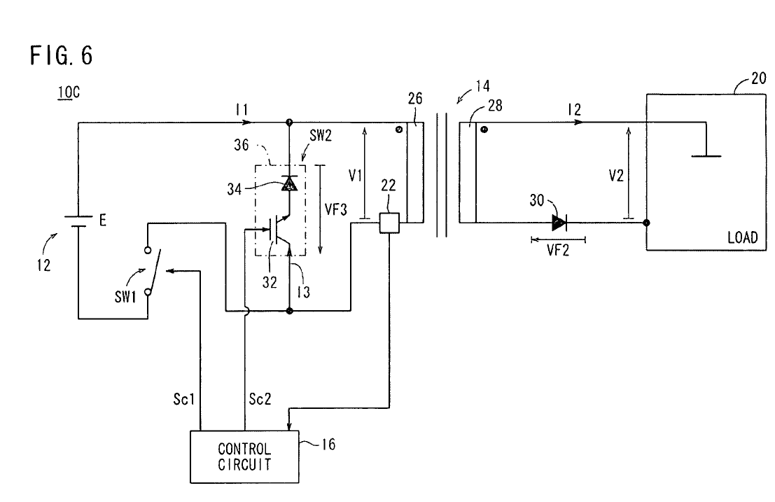

FIG. 6 shows a pulsed power supply 10C according to a third embodiment of the present invention (hereinafter referred to as “third pulsed power supply 10C”).

As shown in FIG. 6, the third pulsed power supply 10C is similar to the second pulsed power supply 10B, but differs therefrom in that the second switch SW2 is connected across the primary winding 26 of the transformer 14 at a position closer to the transformer 14 than the connected position of the first switch SW1.

The across voltage VF3 (turned-on voltage) of the second switch SW2 is smaller than the across voltage VF2 (forward voltage) of the first rectifying circuit 30 (the across voltage (turned-on voltage) VF3<the across voltage VF2 (forward voltage)).

When the second switch SW2 is turned on, the current I1 flows as a current I3 through a short path from the second switch SW2 to the primary winding 26 of the transformer 14 to the second switch SW2. Though the current I1 also undergoes a small energy attenuation, tending to generate a residual current with respect to the exciting inductance, since the current detector 22 and the third circuit 24c operate to keep constant the peak value Ip1 of the current I1 flowing through the primary winding 26 of the transformer 14, an induced energy is prevented from being accumulatively stored by the residual current.

If a workpiece is processed by a plasma using the third pulsed power supply 10C in any of various applications including plasma CVD, plasma PVD, plasma etching, plasma ion implantation, plasma surface modification, plasma electric discharge machining, etc., then the third pulsed power supply 10C can control the pulse duration T3 of its output current depending on the workpiece for increasing the quality of the processed workpiece. Even if the induced energy fluctuates, the third pulsed power supply 10C prevents a residual current from being generated and can produce a stable pulsed output for improved operational availability and reliability. The third pulsed power supply 10C can also employ an inexpensive DC power source as the DC power source 12.

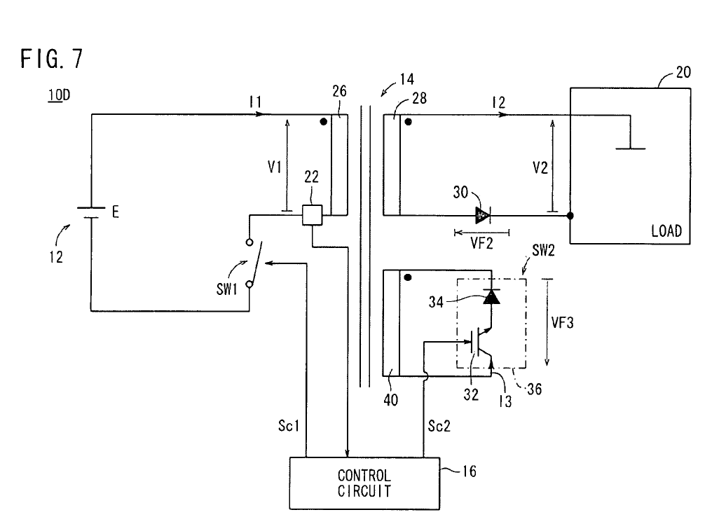

FIG. 7 shows a pulsed power supply 10D according to a fourth embodiment of the present invention (hereinafter referred to as “fourth pulsed power supply 10D”).

As shown in FIG. 7, the fourth pulsed power supply 10D is similar to the second pulsed power supply 10B, but differs therefrom in that the transformer 14 includes, on its secondary side, a winding 40 which is of additive polarity with respect to the primary winding 26, and the second switch SW2 is connected to the winding 40.

The across voltage VF3 (turned-on voltage) of the second switch SW2 is smaller than the across voltage VF2 (forward voltage) of the first rectifying circuit 30.

When the second switch SW2 is turned on, a current I3 flows through a short path from the second switch SW2 to the winding 40 of the transformer 14 to the second switch SW2. Though the current I3 also undergoes a small energy attenuation, tending to generate a residual current with respect to the exciting inductance, since the current detector 22 and the third circuit 24c operate to keep constant the peak value Ip1 of the current I1 flowing through the primary winding 26 of the transformer 14, an induced energy is prevented from being accumulatively stored by the residual current.

If a workpiece is processed by a plasma using the fourth pulsed power supply 10D in any of various applications including plasma CVD, plasma PVD, plasma etching, plasma ion implantation, plasma surface modification, plasma electric discharge machining, etc., then the fourth pulsed power supply 10D can control the pulse duration T3 of its output current depending on the workpiece for increasing the quality of the processed workpiece. Even if the induced energy fluctuates, the fourth pulsed power supply 10D prevents a residual current from being generated and can produce a stable pulsed output for improved operational availability and reliability. The fourth pulsed power supply 10D can also employ an inexpensive DC power source as the DC power source 12.

Although certain preferred embodiments of the present invention have been shown and described in detail, it should be understood that various changes and modifications may be made therein without departing from the scope of the appended claims.

What is claimed is:

1. A pulsed power supply comprising:
a DC power source;
a transformer and a switch which are connected in series with each other across said DC power source;
wherein said pulsed power supply operates to produce a plurality of high-voltage pulses in a repetition of cycles in each of which an induced energy is stored in said transformer when said switch is turned on and a high-voltage pulse is generated across a secondary winding of said transformer when said switch is turned off; and
a current control circuit for controlling a current flowing through a primary winding of said transformer to prevent an induced energy from being accumulatively stored over a plurality of cycles.

2. A pulsed power supply according to claim 1, wherein said current control circuit controls the current flowing through the primary winding of said transformer to keep a peak value of the current constant.

3. A pulsed power supply according to claim 2, further comprising:
current detecting means for detecting the current flowing through the primary winding of said transformer; and
control means for turning off said switch when the current detected by said current detecting means reaches said peak value.

4. A pulsed power supply according to claim 1, further comprising:
a rectifying circuit for supplying a current in one direction through the secondary winding of said transformer;
a second switch connected across the secondary winding of said transformer at a position closer to said transformer than the connected position of said rectifying circuit; and
switching control means for turning on said second switch after elapse of a preset period from the time when said switch is turned off.

5. A pulsed power supply according to claim 4, wherein a voltage applied across said second switch when the second switch is turned on is smaller than a forward voltage applied across said rectifying circuit.

6. A pulsed power supply according to claim 1, further comprising:
a rectifying circuit for supplying a current in one direction through the secondary winding of said transformer;
a second switch connected across the primary winding of said transformer at a position closer to said transformer than the connected position of said switch; and
switching control means for turning on said second switch after elapse of a preset period from the time when said switch is turned off.

7. A pulsed power supply according to claim 6, wherein a voltage applied across said second switch when the second switch is turned on is smaller than a forward voltage applied across said rectifying circuit.

8. A pulsed power supply according to claim 1, further comprising:
a rectifying circuit for supplying a current in one direction through the secondary winding of said transformer;
another winding disposed on a secondary side of said transformer separately from said secondary winding, said other winding being of additive polarity with respect to said primary winding;
a second switch connected in series to said other winding; and
switching control means for turning on said second switch after elapse of a preset period from the time when said switch is turned off.

9. A pulsed power supply according to claim 8, wherein a voltage applied across said second switch when the second switch is turned on is smaller than a forward voltage applied across said rectifying circuit.
